(19) United States
(12) Patent Application Publication
(10) Pub. No.: US 2026/0107646 A1
(43) Pub. Date: Apr. 16, 2026

(54) DISPLAY DEVICE AND METHOD OF MANUFACTURING DISPLAY DEVICE

(71) Applicant: Samsung Display Co., Ltd., Yongin-si (KR)

(72) Inventors: DONG HEE SHIN, Yongin-si (KR); Dongwan Ha, Yongin-si (KR); JUNGHWAN HWANG, Yongin-si (KR)

(73) Assignee: Samsung Display Co., Ltd., Yongin-si (KR)

(21) Appl. No.: 19/249,088

(22) Filed: Jun. 25, 2025

(30) Foreign Application Priority Data
Oct. 10, 2024 (KR) 10-2024-0137468

(51) Int. Cl. H10K 59/124; H10K 59/12; H10K 59/121

(52) U.S. Cl. CPC H10K 59/124; H10K 59/1201; H10K 59/1213

(57) ABSTRACT

Provided is a display device including: a substrate; a thin-film transistor disposed on the substrate; and a light-emitting element electrically connected to the thin-film transistor, wherein the thin-film transistor includes a semiconductor layer and a gate electrode with a first insulating layer between the semiconductor layer and the gate electrode, and the gate electrode includes an opening exposing a portion of the first insulating layer at a position at which the gate electrode overlaps the semiconductor layer.

### CROSS-REFERENCE TO RELATED APPLICATION(S)

This application claims priority to and the benefits of Korean Patent Application No. 10-2024-0137468 under 35 U.S. C. § 119, filed Oct. 10, 2024, in the Korean Intellectual Property Office, the entire contents of which are incorporated herein by reference.

### BACKGROUND

### 1. Technical Field

Embodiments relate to a display device and a method of manufacturing the display device.

### 2. Description of the Related Art

Recently, various types of lightweight and compact flat panel display devices are being developed. Examples of flat panel display devices include liquid crystal displays (LCD), field emission displays (FED), plasma display panels (PDP), and organic light-emitting displays (OLED).

Among the flat panel display devices, organic light-emitting display devices (OLEDs) display images using an organic light-emitting diode which emits light through the recombination of electrons and holes. These OLED devices are receiving attention as next-generation displays because they have fast response speeds and operate with low power consumption.

### SUMMARY

Embodiments provide a display device with improved precision in brightness.

However, embodiments are not limited to those set forth herein. The above and other embodiments will become more apparent to one of ordinary skill in the art to which the disclosure pertains by referencing the detailed description of the disclosure given below.

According to an embodiment of the disclosure, provided is a display device including a substrate; a thin-film transistor disposed on the substrate; and a light-emitting element electrically connected to the thin-film transistor, wherein the thin-film transistor includes a semiconductor layer and a gate electrode with a first insulating layer between the semiconductor layer and the gate electrode, and the gate electrode includes an opening exposing a portion of the first insulating layer at a position at which the gate electrode overlaps the semiconductor layer.

In the embodiment, a first width of the opening in a direction perpendicular to a longitudinal direction of the semiconductor layer may be greater than or equal to a width of the semiconductor layer.

In the embodiment, the gate electrode may include the opening in a central region of the gate electrode.

In the embodiment, a second width of the opening in a longitudinal direction of the semiconductor layer may be about 2 μm to about 4 μm.

In the embodiment, a first width of the opening in a direction perpendicular to a longitudinal direction of the semiconductor layer may be less than a width of the semiconductor layer.

In the embodiment, a difference between the width of the semiconductor layer and the first width of the opening may be about 1 μm to about 2 μm.

In the embodiment, the display device may further include a second insulating layer covering the thin-film transistor, and a source electrode and a drain electrode positioned on the second insulating layer and electrically connected to a source region and a drain region of the semiconductor layer, respectively.

In the embodiment, the opening may be positioned between a central region of the semiconductor layer and either the source region or the drain region.

In the embodiment, the display device may further include a third insulating layer positioned on the source electrode and the drain electrode, wherein the third insulating layer fills the opening.

In the embodiment, the thin-film transistor may include a driving transistor.

According to another embodiment, disclosed is a method of manufacturing a display device, the method including: a first operation of sequentially forming a semiconductor layer, a first insulating layer, and a gate electrode on a substrate; a second operation of forming a second insulating layer on the gate electrode; a third operation of exposing a portion of the gate electrode by patterning the second insulating layer; and a fourth operation of forming an opening in the gate electrode by removing the exposed portion of the gate electrode, wherein the opening is formed at a position overlapping the semiconductor layer.

In the embodiment, the method may further include, between the first operation and the second operation, forming a source region and a drain region by doping the semiconductor region with impurities by using the gate electrode as a mask.

In the embodiment, in case that the second insulating layer is patterned, the source region and the drain region are exposed together.

In the embodiment, the method may further include, after the third operation, forming a source electrode and a drain electrode positioned on the second insulating layer and electrically connected to the source region and the drain region, respectively.

In the embodiment, the method may further include, after the fourth operation, forming a third insulating layer positioned on the source electrode and the drain electrode, wherein the third insulating layer fills the opening.

In the embodiment, the opening may be positioned between a central region of the semiconductor layer and either the source region or the drain region.

In the embodiment, a first width of the opening in a direction perpendicular to a longitudinal direction of the semiconductor layer may be greater than or equal to a width of the semiconductor layer.

In the embodiment, a first width of the opening in a direction perpendicular to a longitudinal direction of the semiconductor layer may be less than a width of the semiconductor layer.

In the embodiment, a difference between the width of the semiconductor layer and the first width may be about 1 μm to about 2 μm.

According to one or more embodiments, there is provided a electronic device including display device, wherein display device includes a substrate, a thin-film transistor on the substrate and a light-emitting element electrically connected to the thin-film transistor, wherein the thin-film transistor comprises a semiconductor layer and a gate electrode with a first insulating layer between the semiconductor layer and the gate electrode, and the gate electrode includes an opening exposing a portion of the first insulating layer at a position at which the gate electrode overlaps the semiconductor layer.

### BRIEF DESCRIPTION OF THE DRAWINGS

The following drawings attached to the specification illustrate preferred embodiments of the disclosure and, together with the detailed description of the disclosure described below, serve to further understand the technical idea of the disclosure; therefore, the disclosure should not be interpreted as being limited to matters described in such drawings.

FIG. 1 is a schematic plan view of an example of a display device according to an embodiment;

FIG. 2 is a schematic block diagram of a structure of the display device of FIG. 1;

FIG. 3 is a schematic diagram of an equivalent circuit of one sub-pixel of the display device of FIG. 1;

FIG. 4 is a schematic plan view of an example of a first transistor arranged in a sub-pixel included in the display device of FIG. 1;

FIG. 5 is a schematic cross-sectional view of an example of cross-section A-A′ of FIG. 4;

FIG. 6 is a graph showing a driving current with respect to a voltage applied to a gate electrode of the first transistor of FIG. 4;

FIGS. 7 to 10 are schematic cross-sectional views of an example of a method of manufacturing the first transistor of FIG. 4;

FIG. 11 is a schematic cross-sectional view of another example of the first transistor arranged in the sub-pixel included in the display device of FIG. 1;

FIG. 12 is a schematic plan view of another example of the first transistor arranged in the sub-pixel included in the display device of FIG. 1; and

FIG. 13 is a schematic diagram of an example in which an electronic device including a display device according to embodiments is implemented as a head-mounted display.

### DETAILED DESCRIPTION OF THE EMBODIMENTS

In the following description, for the purposes of explanation, numerous specific details are set forth in order to provide a thorough understanding of various embodiments or implementations of the invention. As used herein, “embodiments” and “implementations” are interchangeable words that are non-limiting examples of devices or methods disclosed herein. It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in another embodiment.

Unless otherwise specified, the illustrated embodiments are to be understood as providing features of the invention. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the scope of the invention.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

When an element or a layer is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the axis of the first direction X, the axis of the second direction Y, and the axis of the third direction Z are not limited to three axes of a rectangular coordinate system, such as the X, Y, and Z - axes, and may be interpreted in a broader sense. For the purposes of this disclosure, “at least one of A and B” may be understood to mean A only, B only, or any combination of A and B. Also, “at least one of X, Y, and Z” and “at least one selected from the group consisting of X, Y, and Z” may be construed as X only, Y only, Z only, or any combination of two or more of X, Y, and Z. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one element's relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein should be interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art. For example, “about” may mean within one or more standard deviations, or within ±20%, ±10%, or ±5% of the stated value.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

As customary in the field, some embodiments are described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (e.g., microcode) to perform various functions discussed herein and may optionally be driven by firmware and/or software. It is also contemplated that each block, unit, and/or module may be implemented by dedicated hardware, or as a combination of dedicated hardware to perform some functions and a processor (e.g., one or more programmed microprocessors and associated circuitry) to perform other functions. Also, each block, unit, and/or module of some embodiments may be physically separated into two or more interacting and discrete blocks, units, and/or modules without departing from the scope of the invention. Further, the blocks, units, and/or modules of some embodiments may be physically combined into more complex blocks, units, and/or modules without departing from the scope of the invention.

Hereinafter, embodiments will be described in detail with reference to the accompanying drawings, and in the description with reference to the drawings, like reference numerals refer to like elements.

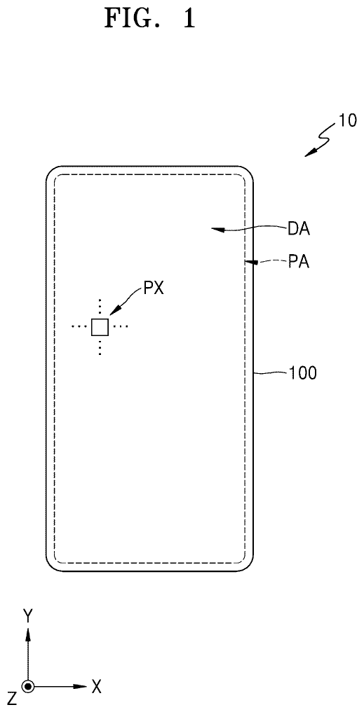

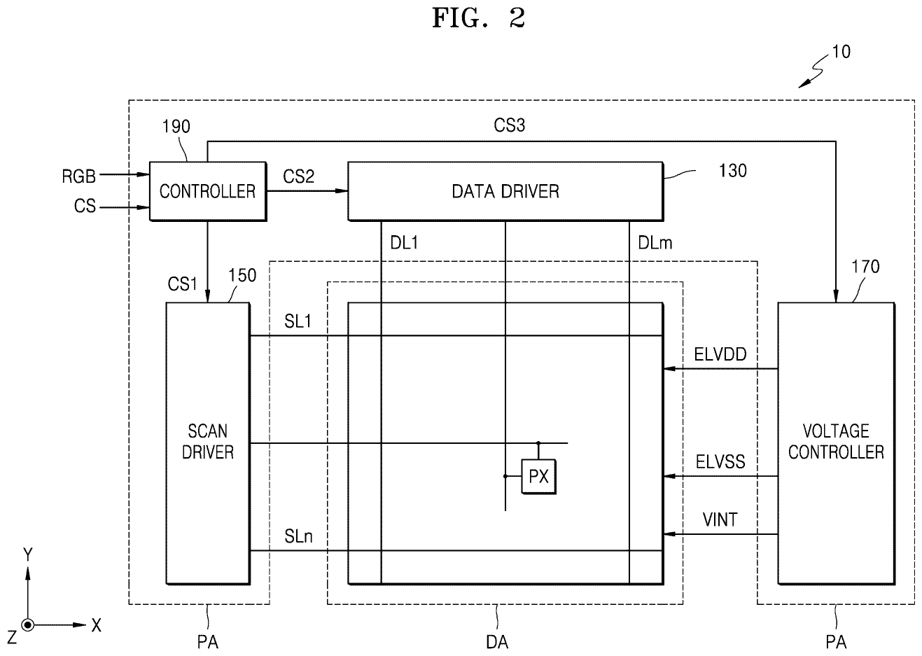

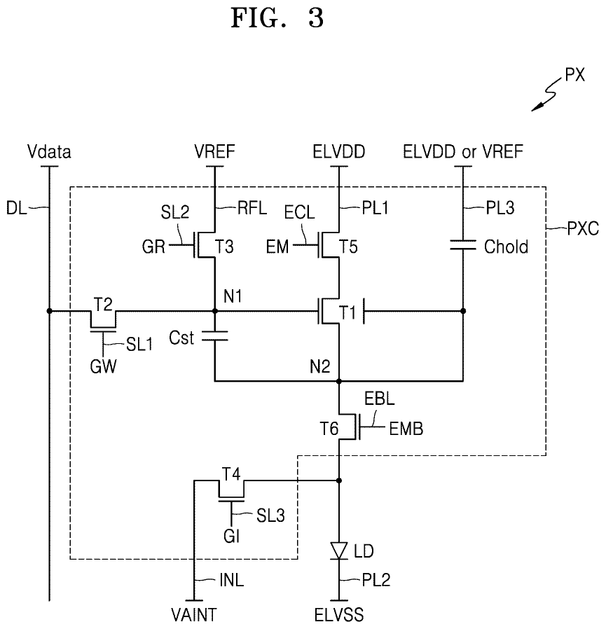

FIG. 1 is a schematic plan view of an example of a display device according to an embodiment, FIG. 2 is a block diagram of a structure of the display device of FIG. 1, and FIG. 3 is a schematic diagram of an equivalent circuit of a sub-pixel of the display device of FIG. 1.

First, referring to FIGS. 1 and 2, a display device 10 according to an embodiment may include a substrate 100 including a display area DA for displaying an image and a peripheral area PA positioned outside the display area DA.

The display area DA may include scan lines SL1 to SLn extending in a first direction X, data lines DL1 to DLm extending in a second direction Y perpendicular to the first direction X, and sub-pixels PX. Here, m and n may be each a natural number. A third direction Z is perpendicular to the plane defined the first direction X and the second direction Y.

Wirings, which apply electrical signals to the sub-pixels PX, may include the scan lines SL1 to SLn, the data lines DL1 to DLm, etc. The scan lines SL1 to SLn are arranged, for example, in rows extending in the first direction X to transmit scan signals to the sub-pixels PX, and the data lines DL1 to DLm are arranged, for example, in columns extending in the second direction Y to transmit data signals to the sub-pixels PX, and the sub-pixels PX may be positioned at intersections the scan lines SL1 to SLn and the data lines DL1 to DLm.

Each sub-pixel PX may include a light-emitting element that emits red light, green light, blue light, or white light. For example, each sub-pixel PX may include an organic light-emitting diode (OLED) as a light-emitting element. However, embodiments are not limited thereto.

A data driver 130, a scan driver 150, a voltage controller 170, and a controller 190 may be arranged in the peripheral area PA. The data driver 130 may provide data signals to the display area DA, the scan driver 150 may provide scan signals to the display area DA, the voltage controller 170 may control voltages supplied to the display area DA, and the controller 190 may control the data driver 130, the scan driver 150, and the voltage controller 170.

The voltage controller 170 may generate and control a first voltage ELVDD, a second voltage ELVSS, and an initialization voltage VINT provided to the display area DA.

The first voltage ELVDD, the second voltage ELVSS, and the initialization voltage VAINT may be applied to the sub-pixels PX. For example, the first voltage ELVDD may be a positive voltage, and the second voltage ELVSS may be a negative voltage or ground voltage. For example, the second voltage ELVSS may have a lower level than the first voltage ELVDD.

The controller 190 may receive image signals RGB and control signals CS from the outside (e.g., a system board). The controller 190 may generate image data by converting a data format of the image signals RGB to match the interface specifications of the data driver 130. The controller 190 may provide image data having a converted data format to the data driver 130.

The controller 190 may generate and output a first control signal CS1, a second control signal CS2, and a third control signal CS3, in response to a control signal CS provided from the outside. The first control signal CS1 may be defined as a scan control signal, and the second control signal CS2 may be defined as a data control signal. The first control signal CS1 may be provided to the scan driver 150. The second control signal CS2 may be provided to the data driver 130. The third control signal CS3 may be applied to the voltage controller 170.

The scan driver 150 may generate scan signals in response to the first control signal CS1. The scan signals may be applied to the sub-pixels PX via the scan lines SL1 to SLn.

The data driver 130 may generate data voltages corresponding to the image data in response to the second control signal CS2. The data voltages may be applied to the sub-pixels PX via the data lines DL1 to DLm. The data driver 130 may simultaneously provide the data voltages, which are generated by a unit of a sub-pixel row, to the data lines DL1 to DLm, so that the data voltages may be simultaneously provided to the sub-pixels PX.

The sub-pixels PX may receive the data voltages in response to the scan signals. The sub-pixels PX may display an image by emitting light with brightness corresponding to the data voltages. The sub-pixels PX may display the image by emitting light sequentially or simultaneously.

Referring to FIGS. 1 to 3, the sub-pixel PX may include a pixel circuit PXC and a light-emitting element LD. For example, the sub-pixel PX may be connected to a scan lines SL (or gate line) and a data line DL. The scan line SL may be one of the scan lines SL1 to SLn of FIG. 2, and the data line DL may be one of the data lines DL1 to DLm of FIG. 2. The scan line SL may include a first scan line SL1, a second scan line SL2, a third scan line SL3, a first emission control line ECL, and a second emission control line EBL.

Driving signals may be applied to the scan line SL and the data line DL. A first scan signal GW may be applied to the first scan line SL1, a second scan signal GR may be applied to a second scan line SL2, and a third scan signal GI may be applied to a third scan line SL3. A first emission control signal EM may be applied to the first emission control line ECL, a second emission control signal EMB may be applied to the second emission control line EBL, and a data signal Vdata (or data voltage) may be applied to the data line DL.

For example, the sub-pixel PX may be further connected to a first voltage line PL1, a second voltage line PL2, a third voltage line PL3, a reference voltage line RFL, and an initialization voltage line INL. Voltages may be applied to the first voltage line PL1, the second voltage line PL2, the third voltage line PL3, the reference voltage line RFL, and the initialization voltage line INL. The first voltage ELVDD may be applied to the first voltage line PL1, the second voltage ELVSS may be applied to the second voltage line PL2, the first voltage ELVDD or a reference voltage VREF may be applied to the third voltage line PL3, the reference voltage VREF may be applied to the reference voltage line RFL, and the initialization voltage VAINT may be applied to the initialization voltage line INL.

A voltage level of the first voltage ELVDD may be higher than a voltage level of the second voltage ELVSS. A voltage level of the reference voltage VREF may be equal to or different from the voltage level of the first voltage ELVDD. A voltage level of the initialization voltage VAINT may be lower than the voltage level of the first voltage ELVDD and higher than the voltage level of the second voltage ELVSS. However, the voltages are not limited thereto, and the voltage levels of the voltages may vary according to the product specifications.

The pixel circuit PXC may include a first transistor T1 (or driving transistor), a second transistor T2, a third transistor T3, a fourth transistor T4, a fifth transistor T5, a sixth transistor T6, a first capacitor Cst (or storage capacitor), and a second capacitor Chold (or hold capacitor).

The first transistor T1 may be electrically connected between the first voltage line PL1 and a second node N2. For example, a first electrode of the first transistor T1 may be connected to the first voltage line PL1 via the fifth transistor T5, and a second electrode of the first transistor T1 may be connected to the second node N2. For example, the first electrode may be a source electrode and the second electrode may be a drain electrode. However, the disclosure is not limited thereto, and the first electrode may be a drain electrode and the second electrode may be a source electrode.

A gate electrode of the first transistor T1 may be connected to a first node N1. For example, the first transistor T1 may further include a bottom electrode (or a second gate electrode) corresponding to the gate electrode. The first transistor T1 may be configured to supply driving current to the light-emitting element LD or control the amplitude of driving current flowing from the first voltage line PL1 to the light-emitting element LD. For example, the first transistor T1 may supply a driving current corresponding to a voltage of the first node N1 to the light-emitting element LD.

The second transistor T2 may be electrically connected between the data line DL and the first node N1. A gate electrode of the second transistor T2 may be connected to the first scan line SL1. The second transistor T2 may be turned on in response to the first scan signal GW of the first scan line SL1. In case that the second transistor T2 is turned on, the data signal Vdata of the data line DL may be transmitted to the first node N1.

The third transistor T3 may be electrically connected between the reference voltage line RFL and the first node N1. A gate electrode of the third transistor T3 may be connected to the second scan line SL2. The third transistor T3 may be turned on in response to the second scan signal GR of the second scan line SL2. In case that the third transistor T3 is turned on, the reference voltage VREF may be transmitted to the first node N1.

The fourth transistor T4 may be electrically connected between an anode electrode of the light-emitting element LD and the initialization voltage line INL. A gate electrode of the fourth transistor T4 may be connected to the third scan line SL3. The fourth transistor T4 may be turned on in response to the third scan signal GI of the third scan line SL3. In case that the fourth transistor T4 is turned on, the initialization voltage VAINT may be transmitted to the anode electrode of the light-emitting element LD.

The fifth transistor T5 may be electrically connected between the first voltage line PL1 and the first transistor T1. A gate electrode of the fifth transistor T5 may be connected to the first emission control line ECL. The fifth transistor T5 may be turned on in response to the first emission control signal EM of the first emission control line ECL.

The sixth transistor T6 may be electrically connected between the second node N2 and the anode electrode of the light-emitting element LD. A gate electrode of the sixth transistor T6 may be connected to the second emission control line EBL. The sixth transistor T6 may be turned on in response to the second emission control signal EMB of the second emission control line EBL.

In case that the fifth transistor T5 and the sixth transistor T6 are turned on, a current path may be formed, through which a driving current may flow from the first voltage line PL1 to the second voltage line PL2 via the pixel circuit PXC and the light-emitting element LD.

The first capacitor Cst may be formed or electrically connected between the first node N1 and the second node N2. A voltage corresponding to the data voltage Vdata may be stored in the first capacitor Cst.

The second capacitor Chold may be formed or electrically connected between the third voltage line PL3 and the second node N2. The second capacitor Chold may stabilize a voltage of the second node N2. The first voltage ELVDD or the reference voltage VREF may be applied to the third voltage line PL3. For example, in case that the first voltage ELVDD is applied to the third voltage line PL3, the third voltage line PL3 may be electrically connected to the first voltage line PL1 or formed integrally (or integral) with the first voltage line PL1. However, the third voltage line PL3 is not limited thereto.

The light-emitting element LD may be electrically connected between the sixth transistor T6 and the second voltage line PL2. For example, the light-emitting element LD may be forward-biased and connected between the second node N2 and the second voltage line PL2. In case that a driving current is supplied from the first transistor T1, the light-emitting element LD may emit light with a brightness corresponding to the driving current.

In an embodiment, the light-emitting element LD may include an OLED. In another embodiment, the light-emitting element LD may include at least one inorganic light-emitting diode. The type, size, and/or number of light-emitting elements LD may vary according to embodiments.

The first to sixth transistors T1 to T6 may be N-type transistors. For example, embodiments are not limited thereto. For example, at least one of the first to sixth transistors T1 to T6 may be changed to a P-type transistor. For example, voltage levels of driving signals for controlling the operation of the transistors may be set according to the type of each transistor.

The first to sixth transistors T1 to T6 may include oxide semiconductors and/or low-temperature polycrystalline silicon (LTPS). For example, at least one transistor including the first transistor T1 may be an oxide semiconductor transistor including an oxide semiconductor.

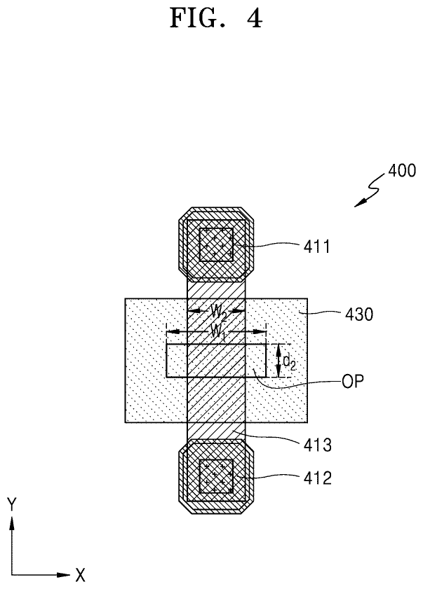

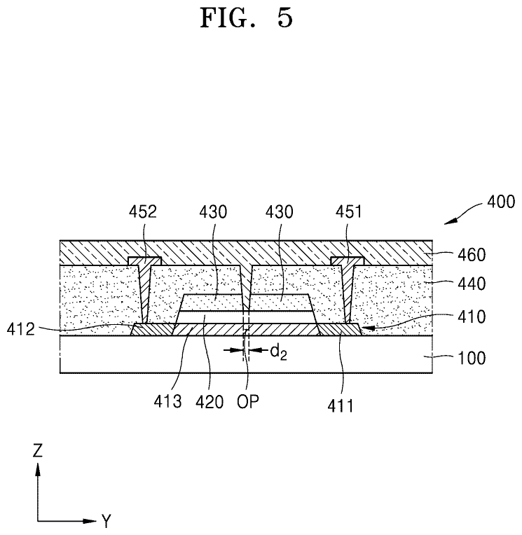

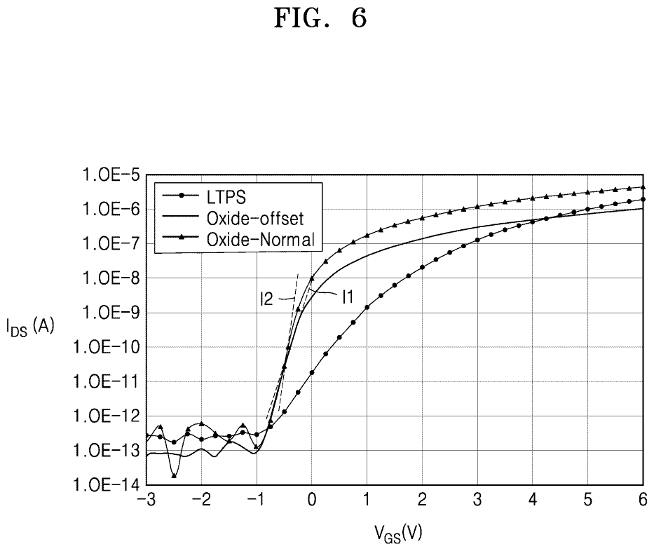

FIG. 4 is a schematic plan view of an example of a first transistor arranged in a sub-pixel included in the display device of FIG. 1, FIG. 5 is a schematic cross-sectional view of an example of a cross-section taken along line A-A′ of FIG. 4, and FIG. 6 is a graph showing a driving current with respect to a voltage applied to a gate electrode of the first transistor of FIG. 4.

Referring to FIGS. 4 and 5, a sub-pixel according to an embodiment may include a substrate 100, a first transistor 400 on the substrate 100, and a light-emitting element electrically connected to the first transistor 400. The first transistor 400 may include a thin-film transistor, and further, the first transistor 400 may include a driving transistor that controls current flowing to the light-emitting element.

For example, the substrate 100 may include a transparent glass material containing SiO₂ as a main component. However, the disclosure is not limited thereto, and the substrate 100 may include a transparent plastic material. Plastic materials may include polyethersulfone (PES), polyacrylate (PAR), polyetherimide (PEI), polyethylene napthalate (PEN), polyethylene terephthalate (PET), polyphenylene sulfide (PPS), polyarylate, polyimide, polycarbonate (PC), cellulose triacetate (TAC), cellulose acetate propionate (CAP), etc.

A semiconductor layer 410 may be formed on the substrate 100. The semiconductor layer 410 may include a source region 411, a drain region 412, and a channel region 413 positioned between the source region 411 and the drain region 412.

For example, the semiconductor layer 410 may include the source region 411 and the drain region 412 formed by doping impurities on both sides of the channel region 413. For example, the impurities vary according to the type of the first transistor T1 and may include an N-type impurity or a P-type impurity. For example, the channel region 413, the source region 411 positioned on a side of the channel region 413, and the drain region 412 positioned on another side of the channel region 413 may be referred to as the semiconductor layer 410.

In case that the source region 411 and drain region 412 are doped with impurities, a self-aligned method in which a gate electrode 430 to be described later is used as a mask may be applied. However, the disclosure is not limited thereto, and a separate mask may be used to dope the semiconductor layer 410 with impurities without using the gate electrode 430 as a mask.

The source region 411 and the drain region 412 may be electrically connected to a source electrode 451 and a drain electrode 452, respectively and the source region 411 or the drain region 412 formed by doping may be interpreted as the source electrode 451 or the drain electrode 452 of the first transistor T1 according to circumstances. Embodiments are not limited thereto. For example, the positions of the source region 411 and the drain region 412 may be interchanged according to the impurities doped into the semiconductor layer 410.

The semiconductor layer 410 may be a layer including an oxide semiconductor. For example, the semiconductor layer 410 may include indium gallium zinc oxide (IGZO). However, the disclosure is not limited thereto, and the semiconductor layer 410 may include polycrystalline silicon.

As an optional embodiment, a buffer layer may be formed between the substrate 100 and the semiconductor layer 410. The buffer layer may block impurities during a crystallization process to form polycrystalline silicon, thereby improving the characteristics of the polycrystalline silicon, and provide a flat surface on the buffer layer.

A first insulating layer 420 covering the semiconductor layer 410 may be formed. A conductive layer including a gate electrode 430 may be formed on the first insulating layer 420. The gate electrode 430 may form the first transistor 400 together with the semiconductor layer 410.

For example, the gate electrode 430 may include an opening OP that exposes a portion of the first insulating layer 420 at a position at which the gate electrode 430 overlaps the semiconductor layer 410. The opening OP may be positioned in a central region of the gate electrode 430.

In case that a voltage applied to the gate electrode 430 is relatively small (e.g., driving current may be about 10⁻¹² A to about 10⁻⁹ A or about 1 picoampere to about 1 nanoampere), a channel, through which current flows, may not be formed properly in the channel region 413 overlapping the opening OP. For example, in case that the voltage applied to the gate electrode 430 is relatively small (hereinafter referred to as a low electric field), the channel region 413 overlapping with the opening OP may act as a resistor.

In case that the driving current applied to the gate electrode 430 according to the voltage exceeds about 1 nanoampere, the current may flow properly in the channel region 413 due to the electric field applied to the channel region 413 by the gate electrode 430 despite the existence of the opening OP.

For example, a first width W₁ of the opening OP may be formed to be greater than or equal to a width W₂ of the semiconductor layer 410, so that the precision of brightness at a low electric field may be improved. For example, the first width W₁ of the opening OP may refer to a length along a direction perpendicular to the second direction Y, which is a longitudinal direction of the semiconductor layer 410.

Referring to FIG. 6, the x-axis denotes a voltage V_{GS} applied to the gate electrode 430, and the y-axis denotes a driving current I_{DS}. The LTPS plotted line illustrates a result of measuring the driving current I_{DS} with respect to the voltage V_{GS} applied to the gate electrode 430 by using LTPS as a semiconductor layer of a driving transistor, the Oxide-Normal plotted line illustrates a result of measuring the driving current I_{DS} with respect to the voltage V_{GS} applied to the gate electrode 430 by using IGZO as a semiconductor layer of a driving transistor, and the Oxide-Offset plotted line illustrates a result of measuring the driving current I_{DS} with respect to the voltage V_{GS} applied to the gate electrode 430 in case that IGZO is used as a semiconductor layer of a driving transistor and the gate electrode 430 includes the opening OP exposing a portion of the first insulating layer 420 at a position where the gate electrode 430 overlaps the semiconductor layer 410.

In case that the semiconductor layer 410 of the first transistor 400 is IGZO, compared to case that the semiconductor layer 410 is low-temperature polycrystalline silicon (LTPS), mobility of electrons increases, enabling low-power operation and improving resolution. However, as shown in FIG. 6, in case that the semiconductor layer 410 is IGZO, there is a large fluctuation in the driving current I_{DS} in response to a change in the voltage V_{GS} applied to the gate electrode 430 at a low electric field. As a result, even with a small change in the voltage V_{GS} applied to the gate electrode 430 at a low electric field, the driving current I_{DS} flowing to the light-emitting element increases significantly, which reduces the precision of the brightness of the light-emitting element.

However, as in an embodiment, in case that the gate electrode 430 includes the opening OP exposing a portion of the first insulating layer 420 at a position overlapping the semiconductor layer 410, the channel region 413 overlapping the opening OP at a low electric field may act as a resistor, so that the range of fluctuation of the driving current I_{DS} according to the voltage V_{GS} applied to the gate electrode 430 may be reduced. As a result, the precision of the brightness of the light-emitting element may be improved by gently controlling the increase in the driving current I_{DS} according to the increase in the voltage V_{GS} applied to the gate electrode 430 at a low electric field.

Referring to FIG. 6, it was identified that a slope l1 of the Oxide-Offset plotted line was smaller than a slope l2 of the Oxide-Normal plotted line at a low electric field as described above. Therefore, as described above, in the case of the Oxide-Offset plotted line at a low electric field, the sensitivity of the light-emitting element to the voltage V_{GS} may decrease. In was confirmed that in case that the driving current exceeds about 1 nanoampere, the slope of the Oxide-Offset plotted line shows a similar tendency to the slope of the Oxide-Normal plotted line.

For example, a second width d₂ of the opening OP in the second direction Y, which is the longitudinal direction of the semiconductor layer 410, may be about 2 μm to about 4 μm. In case that the second width d₂ is less than about 2 μm, a channel may be well formed even in the channel region 413 that overlaps the opening OP at a low electric field, and thus there is a concern that the increase in driving current due to an increase in the voltage V_{GS} applied to the gate electrode 430 may be large. On the other hand, in case that the second width d₂ exceeds about 4 μm, resistance of the channel region 413 overlapping the opening OP at a low electric field may increase significantly, and accordingly, the driving current may decrease, so there is a concern that the brightness of the light-emitting element may decrease.

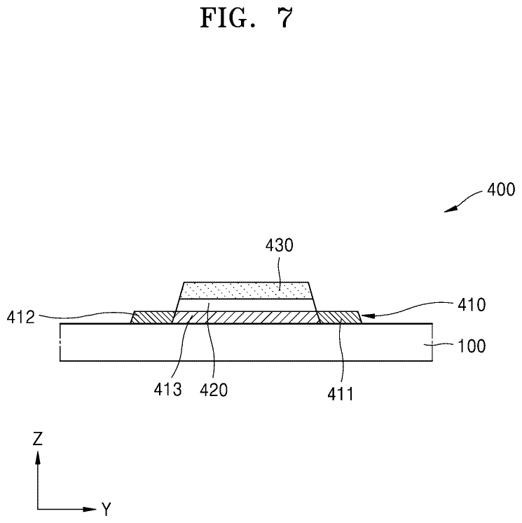

FIGS. 7 to 10 are schematic cross-sectional views of an example of a method of manufacturing the first transistor of FIG. 4.

Referring to FIGS. 7 to 10 together with FIG. 5, a method of manufacturing a display device, according to an embodiment, may include a first operation of sequentially forming the semiconductor layer 410, the first insulating layer 420, and the gate electrode 430 on the substrate 100, a second operation of forming the second insulating layer 440 on the gate electrode 430, a third operation of exposing a portion of the gate electrode 430 by patterning the second insulating layer 440, and a fourth operation of forming the opening OP in the gate electrode 430 by removing the exposed portion of the gate electrode 430.

Referring to FIG. 7, in the first operation of sequentially forming the semiconductor layer 410, the first insulating layer 420, and the gate electrode 430 on the substrate 100, a semiconductor material may be applied over the entire surface of the substrate 100. Afterwards, the semiconductor layer 410 may be formed by patterning a semiconductor material by using a mask process.

As an optional embodiment, a light shielding layer may be formed on the substrate 100 before forming the semiconductor layer 410 to protect the semiconductor layer 410 from external light. For example, a buffer layer covering the entire surface of the substrate 100 may be formed on the light-shielding layer.

The first insulating layer 420 may be formed by depositing an insulating material such as silicon nitride (SiNₓ) or silicon oxide (SiOₓ) on the entire surface of the substrate 100 on which the semiconductor layer 410 is formed. The first insulating layer 420 may include a single layer of silicon nitride (SiNₓ) or silicon oxide (SiOₓ) or multiple layers thereof.

After that, a metal material may be deposited on the first insulating layer 420, and the metal material may be patterned using a mask process to form the gate electrode 430. The gate electrode 430 may be arranged to overlap the semiconductor layer 410. The gate electrode 430 may be formed as a single layer or multiple layers, including at least one of molybdenum (Mo), copper (Cu), titanium (Ti), aluminum (Al), chromium (Cr), gold (Au), nickel (Ni), or neodymium (Nd).

Between the first operation of sequentially forming the semiconductor layer 410, the first insulating layer 420, and the gate electrode 430 on the substrate 100 and the second operation of forming the second insulating layer 440 on the gate electrode 430, an operation of doping an impurity into the semiconductor layer 410 by using the gate electrode 430 as a mask to form the source region 411 and the drain region 412 may be added.

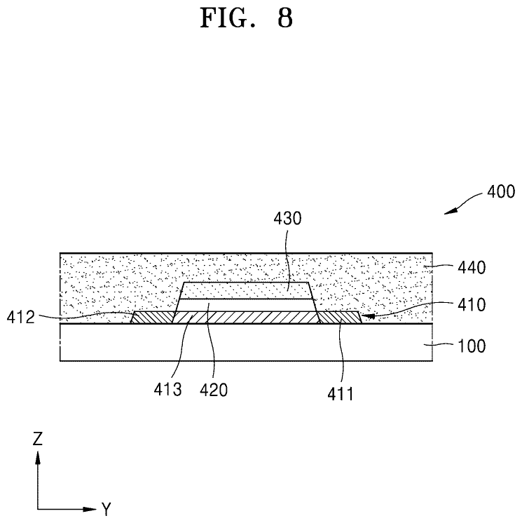

Referring to FIG. 8, the second insulating layer 440 may be formed by depositing an insulating material such as silicon nitride (SiNₓ) or silicon oxide (SiOₓ) on the entire surface of the substrate 100 on which the first insulating layer 420 and the gate electrode 430 are formed. The second insulating layer 440 may include a single layer of silicon nitride (SiNₓ) or silicon oxide (SiOₓ) or multiple layers thereof.

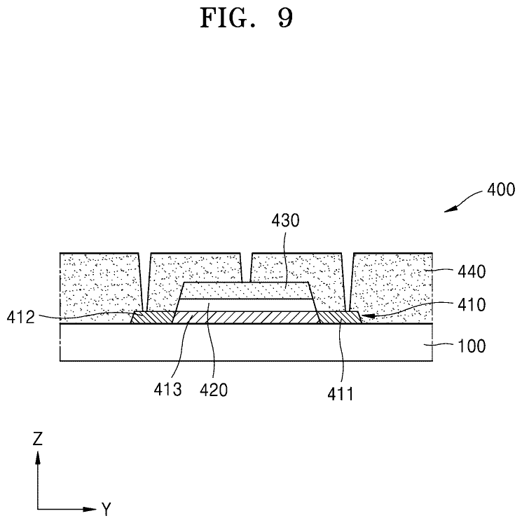

Referring to FIG. 9, the second insulating layer 440 may be patterned using a mask process to form contact holes exposing a portion of the gate electrode 430, the source region 411, and the drain region 412.

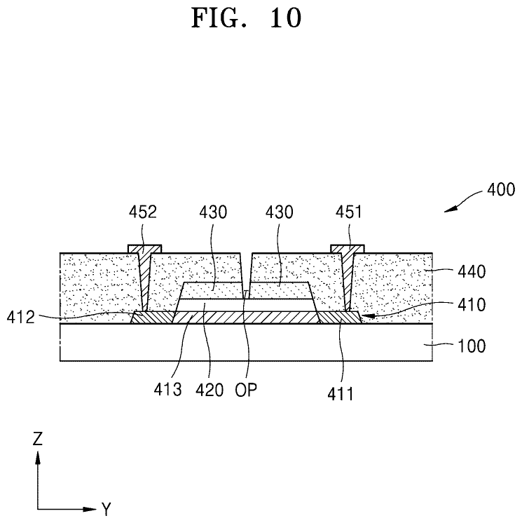

Thereafter, referring to FIG. 10, an operation of forming the source electrode 451 and the drain electrode 452 positioned on the second insulating layer 440 and electrically connected to the source region 411 and the drain region 412, respectively, may be further included. The source electrode 451 and the drain electrode 452 may be formed as a single layer or multiple layers, including at least one of molybdenum (Mo), copper (Cu), titanium (Ti), aluminum (Al), chromium (Cr), gold (Au), nickel (Ni), or neodymium (Nd).

Thereafter, the fourth operation may be performed to remove the exposed gate electrode 430 through a process such as etching to form the opening OP in the gate electrode 430. However, the disclosure is not limited to the order described above, and the fourth operation of forming the opening OP in the gate electrode 430 may be performed first, followed by the operation of forming the source electrode 451 and the drain electrode 452.

Thereafter, a third insulating layer 460 may be formed on the source electrode 451 and the drain electrode 452, and the third insulating layer 460 may fill the opening OP formed in the gate electrode 430.

For example, the method and order of manufacturing a display device, for forming the opening OP in the gate electrode 430, are not limited to the above description, and various methods are possible as long as the opening OP may be formed in the gate electrode 430 by exposing a portion of the first insulating layer 420 at a position overlapping the semiconductor layer 410.

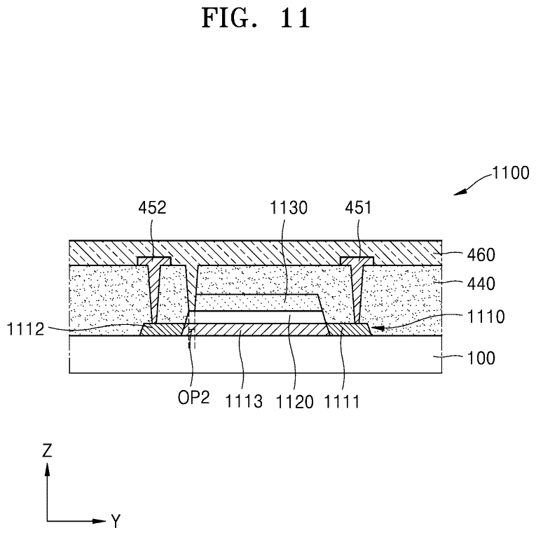

FIG. 11 is a schematic cross-sectional view of another example of a first transistor arranged in a sub-pixel included in the display device of FIG. 1.

Referring to FIG. 11 together with FIG. 5, a sub-pixel according to another embodiment may include the substrate 100, a first transistor 1100 on the substrate 100, and a light-emitting element electrically connected to the first transistor 1100. The first transistor 1100 may include a thin-film transistor, and further, the first transistor 1100 may include a driving transistor that controls current flowing to the light-emitting element.

The first transistor 1100 may include a semiconductor layer 1110 and a gate electrode 1130 with a first insulating layer 1120 therebetween. The semiconductor layer 1110 may include a source region 1111 and a drain region 1112 doped with impurities and a channel region 1113 positioned between the source region 1111 and the drain region 1112.

The gate electrode 1130 may include an opening OP2 exposing a portion of the first insulating layer 1120 at a position at which the gate electrode 1130 overlaps the semiconductor layer 1110. For example, the opening OP2 may be positioned at an end portion of the gate electrode 1130 in the cross-sectional view, as illustrated in FIG. 11.

In case that the opening OP2 is positioned at an end portion of the gate electrode 1130 in the cross-sectional view, the channel region 1113 overlapping the opening OP2 may act as a resistor, as described above. For example, an electric field applied by the gate electrode 1130 to the channel region 1113 may be applied in a single direction of the channel region 1113 rather than in both directions of the channel region 1113, and accordingly, resistance of the channel region 1113 overlapping the opening OP2 may increase. As a result, sensitivity of the light-emitting element to voltage at a low electric field may be reduced, thereby improving precision of the brightness of the light-emitting element.

For example, a position of the opening OP2 is not limited thereto, and in case that the sensitivity of the light-emitting element to voltage is reduced by the resistance of the channel region 1113 overlapping the opening OP2 at a low electric field, the position of the opening OP2 may be in any region where the gate electrode 1130 and the semiconductor layer 1110 overlap each other. For example, the opening OP2 may be positioned between a central region of the semiconductor layer 1110 and either the source region 1111 or the drain region 1112.

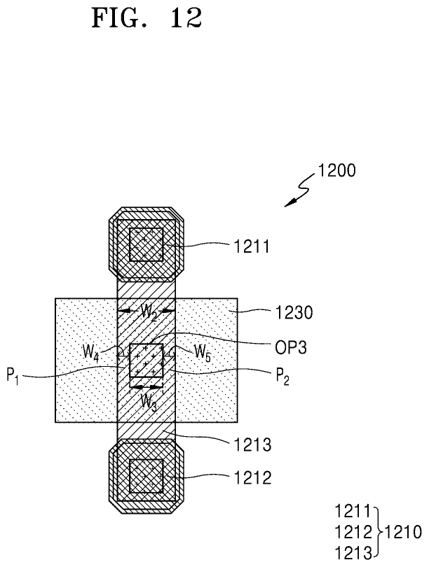

FIG. 12 is a schematic plan view of another example of a first transistor arranged in a sub-pixel included in the display device of FIG. 1.

Referring to FIG. 12, a sub-pixel according to another embodiment may include a first transistor 1200. The first transistor 1200 may include a semiconductor layer 1210 and a gate electrode 1230 with a first insulating layer therebetween. The semiconductor layer 1210 may include a source region 1211 and a drain region 1212 doped with impurities and a channel region 2113 positioned between the source region 1211 and the drain region 1212.

The gate electrode 1230 may include an opening OP3 that exposes a portion of the first insulating layer at a position at which the gate electrode 1230 overlaps the semiconductor layer 1210. The opening OP3 may be positioned between a central region of the semiconductor layer 1210 and either the source region 1211 or the drain region 1212. For example, a first width W₃ of the opening OP3 in a direction perpendicular to a longitudinal direction of the semiconductor layer 1210 may be less than a width W₂ of the semiconductor layer 1210. For example, as illustrated in FIG. 12, the opening OP3 may be positioned within an area where the gate electrode 1230 and the channel region 1213 overlap each other.

For example, a first region P₁ and a second region P₂ may be formed on sides (e.g., opposite sides) of the opening OP3 (sides perpendicular to the longitudinal direction of the semiconductor layer 1210) where the gate electrode 1230 and the channel region 1213 overlap each other. In case that voltage is applied to the gate electrode 1230, a path through which current flows through the first region P₁ and the second region P₂ may be formed. As illustrated in FIG. 12, a width of the first region P₁ may be W₄, and a width of the second region P₂ may be W₅. For example, the width W₂ of the semiconductor layer 1210 may be substantially equal to a sum of the width W₄ of the first region P₁, the width W₅ of the second region P₂, and the first width W₃ of the opening OP3.

Therefore, the opening OP3 may be formed in an island shape within the area where the gate electrode 1230 and the channel region 1213 overlap. In case that the opening OP3 is formed in an island shape, the area where the opening OP3 and the channel region 1213 overlap each other may act as resistor as described above, and thus the precision of the brightness of the light-emitting element may be improved at a low electric field.

For example, even at a low electric field, current may flow through the first region P₁ and the second region P₂, thereby reducing resistance and increasing the power consumption efficiency of the display device. For example, the first width W₃ of the opening OP3 may be designed by comparing and evaluating the effect of improving the precision of the brightness of the light-emitting element due to the increase in resistance with the effect of increasing the power consumption efficiency of the display device through the formation of the first region P₁ and the second region P₂.

Therefore, a difference between the width W₂ of the semiconductor layer 1210 and the first width W₃ of the opening OP3 may be about 1 μm to about 2 μm. In case that the difference between the width W₂ of the semiconductor layer 1210 and the first width W₃ of the opening OP3 is about 1 μm or more, the resistance may decrease and the power consumption efficiency may increase. However, in case that the difference between the width W₂ of the semiconductor layer 1210 and the first width W₃ of the opening OP3 exceeds about 2 μm, the overlapping area between the opening OP3 and the channel region 1213 may decrease, thereby reducing the effect of improving the precision of the brightness of the light-emitting element.

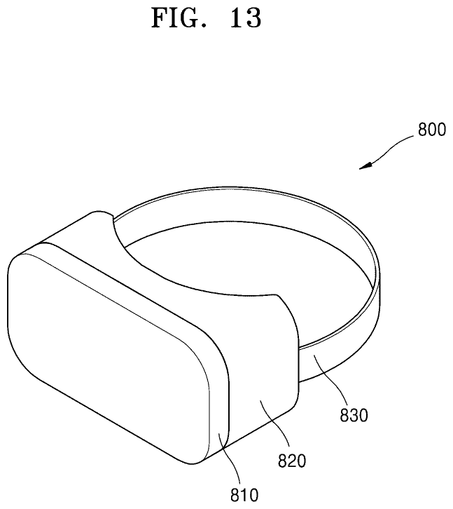

FIG. 13 is a schematic diagram of an example in which an electronic device including a display device according to embodiments is implemented as a head-mounted display.

Referring to FIG. 13, an electronic device including a display device may be implemented as a head-mounted display (HMD) 800. The HMD 800 may include a display unit 810, a main body unit 820, and a wearing unit 830.

For example, the display unit 810 may include the display device according to the embodiments of FIGS. 1 to 12 to implement a screen. The main body unit 820 may include a controller that applies a scan signal and a data signal to the display unit 810, a touch sensor, or an acoustic sensor. A user may wear the HMD 800 using the wearing unit 830.

However, this is an example and the electronic device is not limited to the HDM 800. For example, the electronic device may be any electronic device including a display device such as a virtual reality (VR) device, a mobile phone, a smart phone, a tablet computer, a digital television (TV), a three-dimensional (3D) TV, a personal computer (PC), a home appliance, a laptop computer, a personal digital assistant (PDA), a portable multimedia player (PMP), a digital camera, a music player, a portable game console, a navigator, etc.

According to embodiments, a gate electrode of a driving transistor including a semiconductor layer, an insulating layer, and a gate electrode includes an opening exposing a portion of the insulating layer, so that an increase in a driving current according to an increase in a voltage applied to the gate electrode at a low electric field may be controlled to be gentle, thereby improving the precision of the brightness of the display device.

In concluding the detailed description, those skilled in the art will appreciate that many variations and modifications may be made to the embodiments without substantially departing from the principles and spirit and scope of the disclosure. Therefore, the disclosed embodiments are used in a generic and descriptive sense only and not for purposes of limitation.

What is claimed is:

1. A display device comprising:
a substrate;
a thin-film transistor disposed on the substrate; and
a light-emitting element electrically connected to the thin-film transistor,
wherein the thin-film transistor comprises a semiconductor layer and a gate electrode with a first insulating layer between the semiconductor layer and the gate electrode, and
the gate electrode includes an opening exposing a portion of the first insulating layer at a position at which the gate electrode overlaps the semiconductor layer.

2. The display device of claim 1, wherein a first width of the opening in a direction perpendicular to a longitudinal direction of the semiconductor layer is greater than or equal to a width of the semiconductor layer.

3. The display device of claim 1, wherein the gate electrode includes the opening in a central region of the gate electrode.

4. The display device of claim 1, wherein a second width of the opening in a longitudinal direction of the semiconductor layer is about 2 μm to about 4 μm.

5. The display device of claim 1, wherein a first width of the opening in a direction perpendicular to a longitudinal direction of the semiconductor layer is less than a width of the semiconductor layer.

6. The display device of claim 5, wherein a difference between the width of the semiconductor layer and the first width of the opening is about 1 μm to about 2 μm.

7. The display device of claim 1, further comprising:
a second insulating layer covering the thin-film transistor; and
a source electrode and a drain electrode positioned on the second insulating layer and electrically connected to a source region and a drain region of the semiconductor layer, respectively.

8. The display device of claim 7, wherein the opening is positioned between a central region of the semiconductor layer and either the source region or the drain region.

9. The display device of claim 7, further comprising:
a third insulating layer positioned on the source electrode and the drain electrode,
wherein the third insulating layer fills the opening.

10. The display device of claim 1, wherein the thin-film transistor comprises a driving transistor.

11. A method of manufacturing a display device, the method comprising:
a first operation of sequentially forming a semiconductor layer, a first insulating layer, and a gate electrode on a substrate;
a second operation of forming a second insulating layer on the gate electrode;
a third operation of exposing a portion of the gate electrode by patterning the second insulating layer; and
a fourth operation of forming an opening in the gate electrode by removing the exposed portion of the gate electrode,
wherein the opening is formed at a position overlapping the semiconductor layer.

12. The method of claim 11, further comprising, between the first operation and the second operation, forming a source region and a drain region by doping the semiconductor layer with impurities by using the gate electrode as a mask.

13. The method of claim 12, wherein, in case that the second insulating layer is patterned, the source region and the drain region are exposed together.

14. The method of claim 13, further comprising, after the third operation, forming a source electrode and a drain electrode positioned on the second insulating layer and electrically connected to the source region and the drain region, respectively.

15. The method of claim 14, further comprising, after the fourth operation, forming a third insulating layer positioned on the source electrode and the drain electrode,
wherein the third insulating layer fills the opening.

16. The method of claim 12, wherein the opening is positioned between a central region of the semiconductor layer and either the source region or the drain region.

17. The method of claim 11, wherein a first width of the opening in a direction perpendicular to a longitudinal direction of the semiconductor layer is greater than or equal to a width of the semiconductor layer.

18. The method of claim 11, wherein a second width of the opening in a longitudinal direction of the semiconductor layer is about 2 μm to about 4 μm.

19. The method of claim 11, wherein a first width of the opening in a direction perpendicular to a longitudinal direction of the semiconductor layer is less than a width of the semiconductor layer.

20. An electronic device comprising:
a display device comprising:
a substrate;
a thin-film transistor on the substrate; and
a light-emitting element electrically connected to the thin-film transistor,
wherein the thin-film transistor comprises a semiconductor layer and a gate electrode with a first insulating layer between the semiconductor layer and the gate electrode, and
the gate electrode includes an opening exposing a portion of the first insulating layer at a position at which the gate electrode overlaps the semiconductor layer.
